(19) United States
(12) Patent Application Publication
(10) Pub. No.: US 2007/0103195 A1
(43) Pub. Date: May 10, 2007

(54) High speed and low power SRAM macro architecture and method

(76) Inventors: Jeong Duk-Sohn, Pleasanton, CA (US); Young Tae Kim, San Jose, CA (US)

Correspondence Address: JOHN P. O'BANION;O'BANION & RITCHEY LLP, 400 CAPITOL MALL SUITE 1550, SACRAMENTO, CA, 95814, US

(21) Appl. No.: 11/270,886

(22) Filed: Nov. 7, 2005

(51) Int. Cl. H03K 19/177

(52) U.S. Cl. 326/41

(57) ABSTRACT

Circuits and methods are described for reducing leakage power in integrated circuit devices whose logic transistors (e.g., logic circuits, latches, and/or output stages) are powered through one or more controllable source transistors. By way of example the circuit has at least one source transistor (e.g., power, ground, or both power and ground) for selectively supplying power to a stage within an integrated circuit device. A means for modulating the state of the source transistor operates in response to changes in the operating mode of the integrated circuit to turn on the source transistor prior to turning on the logic transistors, and/or to turn off the source transistor after turning off the logic transistors. In one aspect, the delay prior to turning off the logic transistors can be sufficiently extended to reduce power consumption arising from unnecessarily turning on and off the source transistors for short periods.

### CROSS-REFERENCE TO RELATED APPLICATIONS

This application claims priority from U.S. provisional application Ser. No. 60/626,120, filed on Nov. 8, 2004, incorporated herein by reference in its entirety.

### STATEMENT REGARDING FEDERALLY SPONSORED RESEARCH OR DEVELOPMENT

Not Applicable

### INCORPORATION-BY-REFERENCE OF MATERIAL SUBMITTED ON A COMPACT DISC

Not Applicable

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. §1.14.

### BACKGROUND OF THE INVENTION

1. Field of the Invention

This invention pertains generally to semiconductor logic circuits, and more particularly, to low power static random access memory circuits.

2. Description of Related Art

Static Random Access Memory (SRAM) is a form of electronic data storage which retains data as long as power is supplied. Static RAMs are widely utilized within all manner of electronic devices, and are particularly well-suited for use in portable or hand-held applications, as well as in high performance device applications. In portable or hand-held device applications, such as cell phones, SRAMs provide stable data retention without support circuits, thus keeping complexity low while providing robust data retention.

However, as the transistor has been scaled down due to advancements in process technology the leakage current of turned-off transistors has increased significantly. Therefore, static power consumption due to leakage current represents a larger portion of total power consumption and becomes a serious issue in VLSI (Very Large Scale Integration) design. Among existing techniques for reducing leakage is the use of power and/or ground source transistors for supplying power to portions of the device, such as an output stage, (i.e., driver, or drivers), as shown in FIG. 1 and FIG. 2. The source transistors are turned off to switch off the power and/or ground to the output stage to thus significantly reduce leakage current. The use of source transistors provides a practical method for suppressing leakage current. In an operating mode such as standby mode, source transistors are turned off while they are turned on in normal operating mode.

Yet some issues should be considered carefully when designs are implemented utilizing source transistors in this manner so as not to induce problems such as speed degradation, excessive power consumption, safe maintenance of data information, and so forth.

It should be noted that in designs implemented with source transistors, when the chip operating mode is changed from standby mode (where source transistors are turned off) to normal operating mode, the source transistors can be subject to malfunction because of unsettled power and ground potentials.

Another design issue with the use of source transistors is a result of frequently switching the source transistors, thus turning them off for insufficient periods of time to provide a power savings. As a consequence of charging and discharging the gate capacitance of the large source transistors significant power is unnecessarily consumed.

These shortcomings arise within SRAM circuits and to a lesser extent within other memory circuits and more generally within numerous integrated circuits containing digital logic elements.

Accordingly a need exists for a system and method of reducing static power consumption in digital circuitry, such as SRAM, without compromising data or operational integrity. These needs and others are met within the present invention, which overcomes the deficiencies of previously developed leakage suppression methods and circuits.

### BRIEF SUMMARY OF THE INVENTION

A method and apparatus are described for creating high speed and low power logic circuits, and more particularly memory devices such as static random access memory (SRAM). By way of example a macro architecture is described which provides reduced standby and operating power consumption per cell for any given access speed within SRAM devices. The novel circuitry is applicable to numerous digital logic containing integrated circuits and can be configured with: (1) an early-enable source transistor means to assure proper circuit operation despite switching between standby/idle and normal modes, (2) a late-disable source transistor means to assure proper low-power circuit operation despite switching between normal and standby/idle modes, (3) extending the time period of the late-disable to reduce switching power consumption, and/or (4) a V_{SB} reverse-biasing scheme to reduce cell current leakage. The invention can be practiced with the inventive elements utilized separately, or in combination with what is described herein and what is known to one of ordinary skill in the art, without departing from the teachings of the present invention.

The circuits and methods provide reduced leakage operation while maintaining proper device operation. When the inventive aspects are applied to SRAM memory device circuits the area of the memory can be reduced by about 20%, memory speed increased by about 25% and the leakage current reduced by about one order of magnitude.

The present invention is described as a method and circuitry for controlling leakage within an integrated circuit containing a logic circuit and output driver. One embodiment is drawn to a macro architecture that is duplicated within each of the cells of a memory device, such as a static random access memory.

It has been appreciated in arriving at the present invention that, when using source transistors to control the power being sourced, it would be preferable to activate the source transistor, or transistors, prior to reaching normal operation, such as a memory access or a logic operation.

Accordingly, the power and ground potentials of the transistors of a logic circuit, such as MPL11, MNL11, MPL12 and MNL12 in FIG. 1 and 2, should be settled before the chip enters normal operating mode.

The invention is amenable to being embodied in a number of ways, including but not limited to the following descriptions.

One embodiment of the invention can be generally described as a circuit for controlling source transistors within an integrated circuit device, comprising: (a) at least one source transistor, power or ground or combination of power and ground, configured for selectively supplying power to an integrated circuit device having logic transistors; and (2) means for modulating the state of said source transistor in response to changes in the operating mode of the integrated circuit device to turn on said source transistor prior to turning on the logic transistors.

The logic transistors can comprise a latch (i.e., a portion of a memory), an output stage, and so forth. The source transistor supplies power to an output stage, or a latch, or a combination of latch and output stage within the integrated circuit. The means for modulating the state of the source transistor comprises a circuit configured for receiving a selection signal and communicating the selection signal through a first path delay to the source transistors prior to communicating the selection signal through a second path delay to the logic transistors; wherein the first path delay is less than the second path delay for stabilizing source power prior to activating the logic transistors. The selection signal can comprise a chip select or block select signal.

According to one implementation the means for modulating the state of the source transistor comprises a circuit configured for using the timing difference between asynchronous and synchronous signals to activate said source transistors prior to the logic transistors of the device. The asynchronous signal is configured for arrival prior to the synchronous signal in response to a positive device setup time. According to one implementation the asynchronous signal comprises a chip select signal or block select signal, and the synchronous signal comprises a clock signal or a signal synchronized with the clock. The asynchronous signal can be utilized according to the invention for modulating the state of source transistors for a first logic group, and the synchronous signal is adapted for modulating the state of source transistors for a second, or any subsequent, logic group.

According to one implementation the means for modulating the state of the source transistor, comprises a circuit for controlling the source power between a low-power non-active voltage level and a voltage level sufficient to support normal device activity. In one implementation the circuit comprises an error amplifier whose output level is controlled by a reference voltage, and whose activity state is determined by a device selection signal, or block selection signal.

In one embodiment a means is provided in the circuit for maintaining the source transistor in an on condition for a period of time after the logic transistors are turned off. In a preferred embodiment the period of time is sufficient to provide additional power savings by limiting the unnecessarily frequent switching of the source transistors between on and off. The means for maintaining the source transistor in an on condition, can comprise a circuit configured for activating the source transistor upon receiving an active selection signal, and for delaying the deactivation of the source transistor for a desired period of time after the selection signal returns inactive. In one embodiment the selection signal can comprise a chip select or block select signal.

One embodiment of the invention can be generally described as a circuit controlling source transistors within an integrated circuit device, comprising: (a) at least one source transistor, power or ground or combination of power and ground, configured for selectively supplying power to an integrated circuit device having logic transistors; and (b) means for modulating the state of the source transistor in response to changes in the operating mode of the integrated circuit device to turn on the source transistor and maintain the source transistor in the on state for a period of time (delay period) after the logic transistor is turned off. According to one implementation the delay period is set at a sufficient duration for the application to reduce power consumption and prevent unnecessary dissipation such as arising from too frequent charging and discharging of the gate capacitances of the source transistors.

One embodiment of the invention can be generally described as a circuit for controlling source voltage within an integrated circuit device, comprising: (a) a latch circuit having at least two logic transistors coupled for retaining a binary state which can be accessed for reading or writing in an access mode; (b) at least one source connection, either power or ground, through which a virtual source potential can be maintained; and (c) a means for driving the source connection from a low-power non-active voltage level to a normal access voltage level, configured for supporting normal device read and write access, prior to accessing the logic transistors.

In one embodiment the low-power non-active mode comprises a standby or idle mode implemented with or without data retention. In one embodiment the latch comprises: (a) at least two CMOS inverters in which the output of the first inverter is connected to the input of the second inverter; (b) the output of the second inverter is connected to the input of the second inverter; (c) the sources of the PMOS transistors of the first and second inverter are connected to a given first node; and (d) the sources of the NMOS transistors of the first and second inverter are connected to a given second node. In one mode of this embodiment the source connection is coupled to the first or second node, and wherein an alternate node, first or second, is coupled to a power source or a power source transistor, or is connected to a ground source or a ground source transistor.

According to one implementation the means for driving the source connection is configured for varying the voltage potential of the first node in response to integrated circuit operating mode. According to one implementation the means for driving the source connection can comprise an amplifier (e.g., error detection, differential, comparator, and so forth) configured for controlling the voltage potential of the source connection in response to receiving a reference voltage. In a preferred feature the reference voltage is dynamically or statically programmed.

According to one implementation of the above embodiment a first access path is connected to the output of the first inverter, or a second access path is connected to the output of the second inverter, or a first and second access path are connected to the output of the first and second inverter, respectively. According to one implementation of the above embodiment the access path is controlled by address selection circuitry which turns off the access path irrespective of address information changes when operating in at least one mode which is not a normal access mode (i.e., power down, idle, and so forth). According to one implementation the access path is turned off when there is no address change after a given period of time has elapsed. According to one implementation the source connections are controlled according to the state of the access path.

In one embodiment, additional latch circuitry is included which is configured for storing address information when the access path is turned off, and for recovering address information from this latch when the access path gate is turned on.

One embodiment of the invention can be generally described as a method of controlling low-power operations in an integrated circuit device, comprising: (a) detecting a first selection signal; (b) activating source transistors for supplying power to an output stage, latch, or combination of latch with output stage within the integrate circuit, in response to receipt of the first selection signal; and (c) activating logic transistors within the integrated circuit after activating the source transistors; (d) wherein a sufficient delay is provided between activating the source transistors and activating the logic transistors to stabilize power from the source transistors. One embodiment further comprises deactivating the source transistors within the integrated circuit after deactivating the logic transistors. According to one implementation a sufficient delay period is provided between deactivating the logic transistors and deactivating the source transistors to prevent loss of power stabilization while the circuit is active. According to one implementation a sufficient delay period is introduced between the deactivation of the logic transistors and the source transistors to reduce operating power losses arising from frequent switching of the source transistors on and off.

One embodiment of the invention is a high speed and low power SRAM macro architecture having early-enable late-disabled source transistor control circuitry. According to one implementation the circuitry can include means for disabling the source transistor with some delay to avoid extra power consumption due to frequent transitions in standby mode. According to one implementation the circuitry can incorporate includes means for fast and instant enabling of the source transistor by a chip selection signal in active mode. According to one implementation the circuitry includes reverse bias means for boosting a virtual source node by approximately 0.1 volts to 0.2 volts in standby mode. According to one implementation the circuitry includes means for early-enable of the source transistor with timing margin in active cycle. According to one implementation the circuitry includes means for late-disable of the source transistor after delay. In one mode of this embodiment, the delay period of the late-disable means is of sufficient length to prevent additional power from being consumed in response to the charging and discharging of the gate capacitance.

One embodiment of the invention is a high speed and low power SRAM macro architecture for controlling a source transistor, comprising means for disabling the source transistor after a given delay to avoid extra power consumption due to frequent power transition in standby mode; and means for fast and instant enabling of the source transistor by a chip selection signal in active mode. According to one implementation a means is provided for boosting a virtual source node by approximately 0.1 volts to 0.2 volts in standby mode.

One embodiment of the invention is a high speed and low power SRAM macro architecture for controlling a source transistor, comprising means for early-enable of the source transistor with timing margin in active, cycle; and means for late-disable of the source transistor after delay. According to one implementation a means are also provided for boosting a virtual source node by approximately 0.1 volts to 0.2 volts in standby mode.

One embodiment of the invention is a method for controlling a source transistor for high speed and low power SRAM operation, comprising providing for disabling the source transistor with some delay to avoid extra power consumption due to frequent transition in standby mode; and providing fast and instant enabling of the source transistor by a chip selection signal in active mode. According to one implementation the reverse bias is provided to boost a virtual source node by approximately 0.1 volts to 0.2 volts in standby mode.

One embodiment of the invention is a method for controlling a source transistor for high speed and low power SRAM operation, comprising early-enable of the source transistor with timing margin in active cycle; and late-disable of the source transistor after delay. According to one implementation the reverse bias is provided for boosting a virtual source node by approximately 0.1 volts to 0.2 volts in standby mode.

Described within the teachings of the present invention are a number of inventive aspects, including but not necessarily limited to the following.

An aspect of the invention is that of providing low leakage logic circuit operation in response to modulating source transistor state

Another aspect of the invention is that of providing low leakage control circuits and methods which can be utilized on digital integrated circuits including logic, memory, static memory, dynamic memory, and so forth.

Another aspect of the invention is providing a high-speed low-power SRAM macro architecture.

Another aspect of the invention is an SRAM architecture in which source transistors are disabled responsive to a delay to prevent additional power consumption.

Another aspect of the invention is an SRAM architecture in which the source transistor, or transistors, is activated prior to the circuit entering normal operating mode.

Another aspect of the invention is an SRAM architecture providing reverse biasing of the virtual source nodes.

Another aspect of the invention is a logic circuit having power and/or ground source transistors that are controlled according to different operating modes.

Another aspect of the invention is a logic circuit having power and/or ground source transistors that are controlled by the same inputs but which are subject to different path delays.

Another aspect of the invention is a logic circuit having an input signal which is a chip disable signal or block disable signal.

Another aspect of the invention is a logic circuit in which the input signal is chip disable signal or block disable signal.

Another aspect of the invention is a logic circuit in which the source transistor control signal is subject to a longer path delay.

Another aspect of the invention is a logic circuit in which the source transistor, or transistors, is turned off by using the timing difference between asynchronous and synchronous signals.

Another aspect of the invention is a logic circuit in which the source transistors are controlled in response to the asynchronous signals arriving earlier than the synchronous signal (i.e., has a positive setup time).

Another aspect of the invention is a logic circuit in which the asynchronous signal is a chip disable signal or block disable signal.

Another aspect of the invention is a logic circuit in which the synchronous signal is a clock signal or a signal synchronized with a clock signal.

Another aspect of the invention is a logic circuit in which if there are more than one source transistor (or one set of source transistors), the source transistors are grouped such that the first group is controlled by the first asynchronous signal and the second group is controlled by the first synchronous signal.

Another aspect of the invention is a logic circuit having a first asynchronous signal arriving earlier than the first synchronous signal.

Another aspect of the invention is a logic circuit containing two CMOS inverters in which the output of the first inverter is connected to the input of the second inverter, and the output of the second inverter is connected to the input of the second inverter, and the sources of the first and second inverters' PMOS transistors are connected to a certain first node, and the sources of the first and second inverters' NMOS transistors are connected to a certain second node, and a power or power source transistor is connected to the first node, and a ground or ground source transistor is connected to the second node.

Another aspect of the invention is a CMOS logic circuit in which the potential of the first node varies in response to operating mode.

Another aspect of the invention is a CMOS logic circuit wherein the potential of the first node is lower than in normal mode while in a mode other than normal operating mode.

Another aspect of the invention is a CMOS logic circuit in which modes other than normal access mode include standby or idle mode which are implemented either with or without data retention.

Another aspect of the invention is a CMOS logic circuit in which the potential of the second node varies in response to operating mode.

Another aspect of the invention is a CMOS logic circuit in which the potential of the second node is higher than in normal mode while in modes other than the normal mode.

Another aspect of the invention is a CMOS logic circuit in which the power source transistor is PMOS, NMOS, or a combination of PMOS and NMOS transistors.

Another aspect of the invention is a CMOS logic circuit in which the ground source transistor is PMOS, NMOS, or a combination of PMOS and NMOS transistors.

Another aspect of the invention is a CMOS logic circuit in which the gate potential of the power source transistor is varied in response to the operating mode.

Another aspect of the invention is a CMOS logic circuit wherein the gate potential of the NMOS power source transistor is higher than the potential in normal access mode.

Another aspect of the invention is a CMOS logic circuit wherein the gate potential of the NMOS power source transistor is equal to or less than the level or a certain level less than that of normal mode while in modes other than normal access mode.

Another aspect of the invention is a CMOS logic circuit wherein the modes other than normal access mode include standby or idle mode with or without data retention.

Another aspect of the invention is a CMOS logic circuit in which the gate potential of the PMOS ground source transistor is lower than ground level in normal access mode.

Another aspect of the invention is a CMOS logic circuit wherein the gate potential of the PMOS ground source transistor is equal to or higher than ground level or a certain level higher than that of normal mode while the circuit is in modes other than normal access mode.

Another aspect of the invention is a CMOS logic circuit wherein the modes other than normal access mode include standby or idle mode with or without data retention.

Another aspect of the invention is a CMOS logic circuit wherein the gate potential of the NMOS power source transistor is controlled by a reference voltage and an error detection amplifier.

Another aspect of the invention is a CMOS logic circuit having a reference voltage which is either dynamically or statically programmed.

Another aspect of the invention is a CMOS logic circuit wherein the gate potential of the PMOS power source transistor is controlled so that the potential of the first node is lower than that of normal access mode, while in modes other than normal access mode.

Another aspect of the invention is a CMOS logic circuit wherein the gate potential of the PMOS power source transistor is higher than in normal access mode.

Another aspect of the invention is a CMOS logic circuit in which the gate potential of the PMOS power source transistor is controlled by a reference voltage and an error detection amplifier.

Another aspect of the invention is a CMOS logic circuit in which the gate potential of the NMOS power source transistor is controlled by a reference voltage and an error detection amplifier.

A still further aspect of the invention is to provide methods of reducing static power consumption which can be implemented using conventional integrated circuit fabrication techniques.

Further aspects of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings which are for illustrative purposes only:

FIG. 1 is a schematic of a conventional MTCMOS circuit having ground and source transistors for reducing standby leakage.

FIG. 2 is a schematic of a conventional self-reverse biasing circuit having ground and source transistors for reducing standby leakage.

FIG. 3 is a schematic of a CMOS latch circuit having ground and source transistors for reducing standby leakage.

FIG. 4 is a schematic of a circuit using source transistors according to an aspect of the present invention, shown providing a combination of early-enable and late-disable of the source transistors.

FIG. 5 is a timing diagram of the circuit shown in FIG. 3 according to an aspect of the present invention.

FIG. 6 is a schematic of a circuit using source transistors according to an aspect of the present invention, shown using an NMOS ground source transistor.

FIG. 7 is a schematic of a circuit using source transistor grouping according to an aspect of the present invention, showing two groups of logic being controlled.

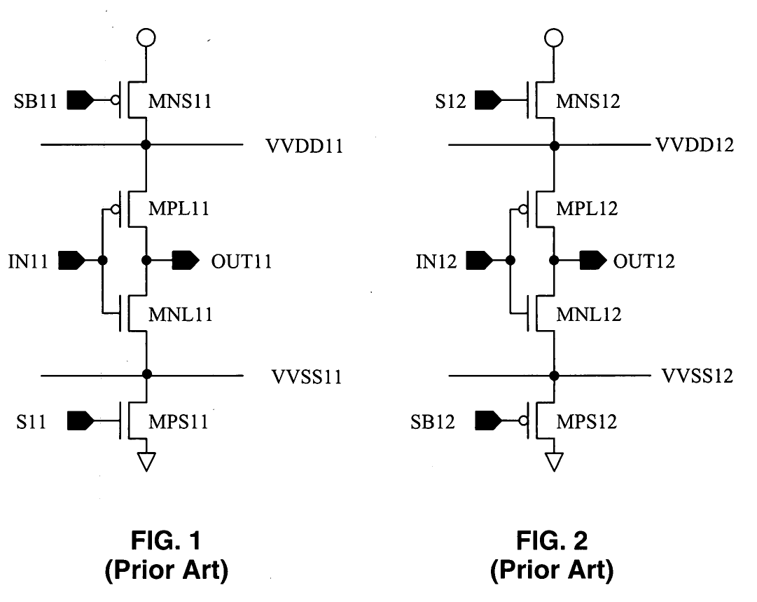

### DETAILED DESCRIPTION OF THE INVENTION

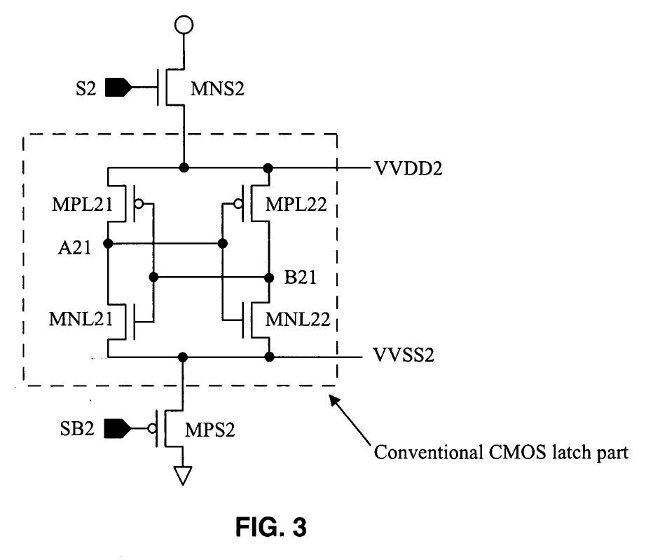

Referring more specifically to the drawings, for illustrative purposes the present invention is embodied in the apparatus generally shown in FIG. 3 through FIG. 7. It will be appreciated that the apparatus may vary as to configuration and as to details of the parts, and that the method may vary as to the specific steps and sequence, without departing from the basic concepts as disclosed herein.

FIG. 3 illustrates one aspect of the invention in which source transistors are utilized for modulating the power supplied to a conventional CMOS latch. When the source transistors are active, the latch can store and maintain data information. Problems can arise, however, when turning off the source transistors because in many applications it is desirable that the latch should maintain the data bit as long as power is supplied to the device. The present invention describes methods and circuits for controlling the state of the source transistors in latches, memories, and logic circuits in general.

One of the principles of the present invention is that early enabling of source transistors is beneficial toward avoiding logic circuit malfunction. The teachings herein describe embodiments and methods to provide early enabling of the source transistors and other related methods. In certain embodiments different delays are provided, such as in the signal and circuit path, as well as the use of different control signals, and so forth.

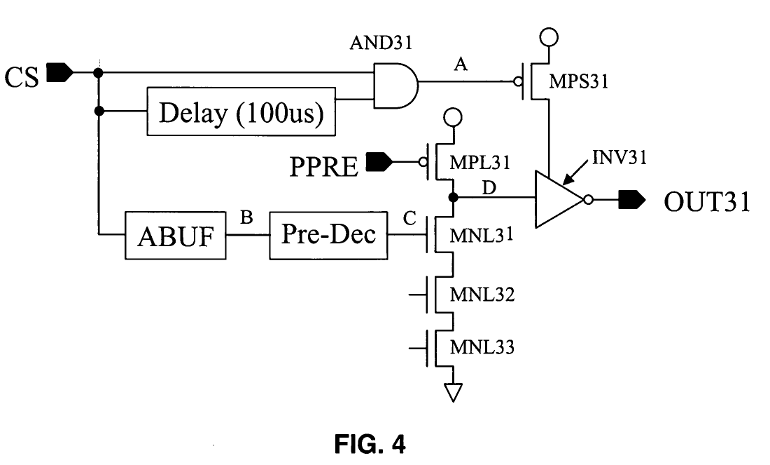

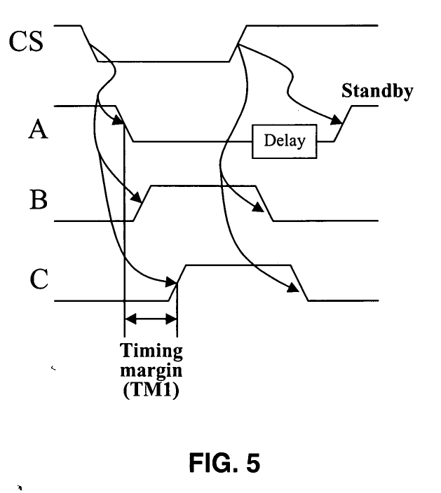

FIG. 4 illustrates by way of example an embodiment in which the address path has a different signal delay, with FIG. 5 depicting the signal timing.

Considering the circuit of FIG. 4, it is assumed that inverter INV31 is subject to high leakage currents as it is typically much larger than the devices internal to the integrated circuit. A power source transistor MPS31 is added to a PMOS source transistor of INV31 to suppress leakage current. It should be appreciated that an embodiment can be created with the NMOS source transistor as shown in FIG.2 (MNS12). When a chip selection signal (CS) is enabled (low enabling signal as depicted in FIG. 5) node A goes low and activates (turns on) source transistor MPS31.

The chip selection signal has another path to enable address buffers to receive addresses (ABUF). Received addresses are pre-decoded and node C goes to high after some time delay. A precharge signal (PPRE) is disabled before node C goes to high to eliminate a static current path. When all gate signals of MNL31, MNL32 and MNL33 become high, node D is discharged and goes to low. The low potential of node D turns on the PMOS transistor of INV31 and makes the output node (OUT31) become high.

It should be noted that before node D goes low and turns on the PMOS transistor of INV31, the power line of INV31 should be settled and therefore, the power source transistor MPS31 must be turned on before node D goes low. In this circuit implementation, since the power source transistor, MPS31, is controlled and enabled by using the same signal but subject to different signal delay (i.e., short signal delay), MPS31 can be turned on earlier so as not to cause any malfunction of inverter circuit, INV31. As shown in FIG. 5, there is a timing margin (TM1) between signal A and signal C to control the source transistor properly.

Another method described herein for controlling source transistor activity is utilizing different forms of signals on the chip. For example, some asynchronous signals such as chip selection (CS) enter the chip before the clock with set-up time margin. Therefore, information associated with the early arrival of an asynchronous signal, such as chip select, can be used to turn on the source transistor even though other inputs, such as addresses, are captured at a rising or a falling edge of a synchronous signal, such as the clock.

FIG. 4 and FIG. 5 also show a method of preventing unnecessary enabling and disabling of the power source transistors. It will be noted that undue power can be consumed when the circuit enables and disables the power transistors too frequently, which may arise for example when the source transistors are deactivated between sequential accesses. Additional power is consumed in response to the too frequent deactivation in response to charging and discharging of the input capacitors.

To overcome this shortcoming, an aspect of the invention provides for disabling of the source transistors after some delay even though a disable signal is activated (i.e., chip select gone inactive). In the example embodiment of FIG. 4, even though the chip selection signal (CS) goes high, the potential of node A goes high after a desired signal delay, (i.e., 100 microseconds) such as in response to a delay circuit (marked ‘Delay’ in FIG. 4) or other means of introducing a sufficient signal delay to assure power stability from the source transistors. In this given instance the sufficient delay assures that the source transistor(s) remain on for a short period after the chip select signal returns inactive. Only during a period of relative inactivity, as determined by the delay, does the source transistor get switched back off, thus reducing the power loss associated with capacitive charging and discharging.

It should be appreciated that since the source transistor is of a size that allows it to supply sufficient current to logic circuits, the power consumption due to charging and discharging of its gate capacitance can be a significant factor. Therefore, the use of the delay assures that the chip is virtually in standby mode since CS hasn't gone low for the delay period as a condition of switching off the source transistor.

The delay can be generated in any desired manner, whether static, programmable or less preferably in response to variables or receipt of other signals, and the like. It will be appreciated that the optimum duration of the delay depends on the circuit, its application and use, so as to minimize power consumption. One aspect of the present invention provides a programmable delay period toward allowing the user to optimize their specific implementation. By way of example, the delay can be programmed by means of blowing fuses.

In another aspect of the invention leakage current can be reduced in a latch circuit, such as a conventional CMOS latch, to add source transistors and control without introducing a speed delay. FIG. 3 described a CMOS latch with an NMOS power source transistor and PMOS ground source transistor. When data stored in the CMOS latch does not need to be maintained then the source transistors, such as MNS2 and MPS2 in the example, can be switched off to eliminate leakage paths.

However, in the case where data stored on the CMOS latch should be maintained, then the source transistors cannot be switched off. In accord with this aspect of the invention the gate potentials of NMOS and PMOS source transistors (MNS2 and MPS2) can be controlled to provide different voltage levels than those present during normal operation. By way of example, the gate potential of NMOS source transistor (MNS2) can be changed from a boosted voltage which is greater than V_{DD} (>V_{DD}) to a voltage at V_{DD}, (=V_{DD}) and the gate potential PMOS source transistor (MPS2) can also be changed from a boosted voltage lower than V_{SS} (<V_{SS}) to V_{SS} (=V_{SS}). Therefore, potential levels of (Virtual Voltage_{NNX}) VV_{DD2} and VV_{SS2} become V_{DD}−Vₜₙ (MNS2) and Vₜₚ (MPS2), respectively, where Vₜₙ (MNS2) and Vₜₚ (MPS2) are threshold voltages of MNS2 and MPS2, respectively. The changed potential levels of VV_{DD2} and VV_{SS2} can increase threshold voltages of CMOS latch transistors. For example, a bulk-to-source voltage of MPL21 and MPL22 is lowered by Vₜₙ (MNS2) and a source-to-bulk voltage of MNL21 and MNL22 is increased by Vₜₚ (MPS2), respectively. Utilizing the methods of these voltage changes can result in increased threshold voltages for CMOS latch transistors and therefore, the leakage current flowing through the CMOS latch can be suppressed.

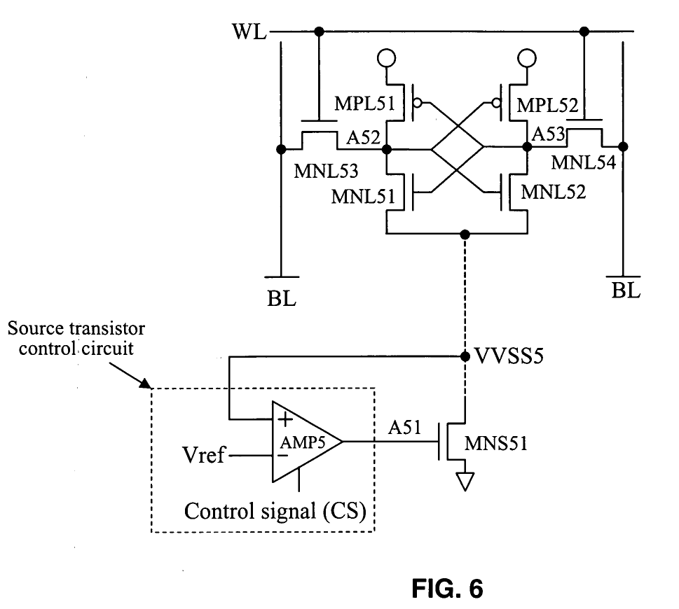

FIG. 6 illustrates another example embodiment of a logic circuit with NMOS ground source transistor (MNS51) in a SRAM (Static Random Access Memory) cell. It should be appreciated that similar circuits can be utilized with regard to the bit line sense amplifiers of DRAM (Dynamic Random Access Memory). In this implementation, the virtual ground potential (VV_{SS5}) can be arbitrarily controlled by a reference voltage (V_{REF}) and an amplifier, such as error detection amplifier (AMP5). The ground potential is then switched between an active and inactive logic circuit mode in response to changes in the device mode, for example as reflected by a selection signal such as a chip select (CS) or block select signal. The reference voltage levels can be set by different methods such as fuse options. One advantage of this technique is controllability of virtual ground level (VV_{SS5}). It should be appreciated that a similar structure can be alternatively, or additionally, implemented for controlling the virtual V_{DD} potential to the latch.

In the CMOS latch described in FIG. 3, the virtual power and ground levels are determined by threshold voltages of NMOS and PMOS source transistors and are not controllable. Such levels are sensitive to chip operating conditions like temperature, operating voltage, and so forth and are also susceptible to fabrication process variations. For example, the threshold voltage of MOS transistor decreases when temperature increases. Therefore, a difference between actual and virtual power and ground levels decreases when temperature increases. Thus, even though leakage current becomes more serious at high temperature, leakage suppression due to effect of threshold voltage increase becomes less.

In contrast, this aspect of the invention provides effective leakage suppression as-represented by FIG. 6 since the virtual power and ground levels can be controlled in response to the V_{ref} level. Any of a number of techniques can be adopted for controlling and programming reference levels appropriately. The state of the ground source transistor (MNS51) can be controlled by the circuit in order that it is turned on prior to enabling of the word line (WL) to prevent access (i.e., read) speed degradation. In addition the ground source transistor can be turned off after a certain delay by using control signals such as chip selection (CS) as described in relation to FIG. 4.

The level of V_{ref} is set for a given application in response to intended operating temperature, voltage and circuit process characteristics. When the chip selection signal (CS) goes to low, node A51 goes to high (or a higher voltage than V_{DD} to increase the current driving capability of MNS51 for faster read speed) and turns on MNS51. When word line (WL) goes to high, a bit line (BL or BL-bar) is discharged according to data stored in the CMOS latch and a normal read or other access operation can be performed.

The delayed source transistor deactivation aspect of the invention can be selectively applied in response to the chip being idle for a sufficiently long period of time after completing an operation. The length of the period of time can be considered sufficient when it reduces unnecessarily turning off the source transistor for short periods of time from which a power savings will not accrue, or otherwise based on application and operation to reduce power consumption compared with lesser time periods.

For example, after the memory cell is not accessed for a long time after performing a read operation, the chip selection signal (CS) doesn't go to high and the word line remains enabled. In this situation, since the word line is high, the pass gate transistors MNL53 and MNL54 are turned on. Accordingly, leakage current from a bit line load (not shown here) to the pull-down transistor (MNL51 or MNL52) of the SRAM cell is added to the leakage current of the CMOS latch. Therefore, in this situation, after a certain delay transpires as determined by a signal or a combination of signals, the word line level transitions to low and information for the word line can be stored at registers, and the ground source transistor (MNS51) is controlled to boost a potential of virtual ground (VV_{SS5}). When a new operation starts, the potential levels of node A52 and A53 can be refreshed and restored back to a previous state by turning on the word line and controlling the source transistor.

The embodiment represented by FIG. 6 shows a circuit containing two CMOS inverters in which the output of the first inverter is connected to the input of the second inverter, and the output of the second inverter is connected to the input of the second inverter. The sources of the first and second inverters' PMOS transistors are connected to a certain first node, and the sources of the first and second inverters' NMOS transistors are connected to a certain second node. A power or power source transistor is connected to the first node, and a ground or ground source transistor is connected to the second node. The first access path (e.g., read or write) is connected to the output of the first inverter, and/or the second access path is connected to the output of the second inverter.

The access path in the circuit in this embodiment is preferably controlled by the circuitry maintaining the address information, while in a mode other than the normal access mode, the access path is turned off irrespective of the address information change and the address information is retained elsewhere. In one mode the access path is turned off when there is no address change for a certain period. In one mode the access path is turned off when there is no address change for a certain period, and the address information is stored elsewhere, and the power and/or source transistors in the circuitry controlling the access path are turned off.

In one embodiment the address information is stored elsewhere and the access path gate can be turned off after a certain delay or in response to a given control signal. The voltage potential of the first node is lowered a given amount below that of normal access mode, and the voltage potential of the second node is raised by a given level above that of normal access mode.

The access path gate is turned on by another control signal or command, and the potential of first and second nodes are restored to the normal access mode level. In one mode the access path gate is controlled by circuitry which also controls power and/or ground source transistors, wherein the source transistors are modulated in response to the state of the access path gate. In one mode the power and/or ground source transistors are turned off when the access path gate is turned off.

In one embodiment the circuitry contains a latch that stores the address information when the access path gate is turned off, and the address information is recovered from this latch when the access path gate is turned on. In one mode, other than normal access mode, the access path is turned off earlier than in normal mode and the address is stored elsewhere, and when the access path gate is turned on by a certain control signal or command the stored address information is used.

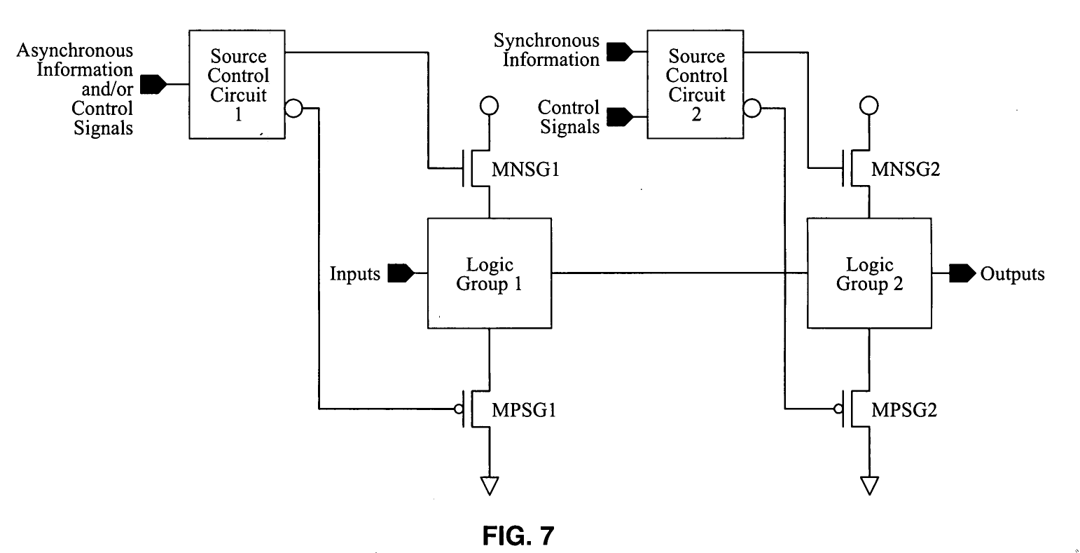

FIG. 7 illustrates an example embodiment of source transistor grouping. The use of grouping allows power to be applied in response to the circuit timing so that overall power use can be reduced without introducing instability into circuit operation. By way of example the embodied circuit shows the use of asynchronous and synchronous signals for controlling source transistors in the respective groups. It should be appreciated, however, that other mechanisms can be utilized for controlling the source transistors respective to group (e.g., delays, delay offsets from asynchronous and/or synchronous signals, and the like). A first logic group is represented with source transistors MNSG1 (power source) and MPSG1 (ground source) as controlled by Source Control Circuit 1 in response to asynchronous information and/or control signals. A second logic group is represented with source transistors MNSG2 (power source) and MPSG2 (ground source) as controlled by Source Control Circuit 2 in response to synchronous information and/or control signals. In this simple example the first logic group receives an input signal and generates an output which is propagated through the second logic group.

One benefit from using asynchronous signals arriving earlier than synchronous signals is to provide for fast activation of the source transistors and therefore provide a timing margin for logic operation. It should be appreciated that the arrival of asynchronous signals cannot be predicted, and further that the state of asynchronous signals may change even when the chip is in idle or standby mode.

For a logic group (i.e., logic group 1 in the figure) which is enabled prior to other logic groups (i.e., logic group 2 in the figure) the state of the source transistors, such as MNSG1 and MPSG1, are modulated by a control circuit (i.e., source control circuit 1) subject to control from asynchronous information for fast enabling. The arrangement of the circuit provides additional timing margin for the second logic group, wherein the source transistors can be activated in response to the combination of synchronous information and/or control signals. In this example the source transistors supply power to the second stage logic only in response to the chip commencing to perform a valid operation.

It will be appreciated that source transistors may be grouped into more than two groups and that the method is amenable for use with single source transistors as well as the dual power and ground source transistors as shown.

Although the description above contains many details, these should not be construed as limiting the scope of the invention but as merely providing illustrations of some of the presently preferred embodiments of this invention.

Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

What is claimed is:

1. A circuit for controlling source transistors within an integrated circuit device, comprising:
at least one source transistor, power or ground or combination of power and ground, configured for selectively supplying power to logic transistors within an integrated circuit device; and
means for modulating the state of said source transistor in response to changes in the operating mode of the integrated circuit device to turn on said source transistor prior to turning on the logic transistors.

2. A circuit as recited in claim 1, wherein said logic transistors comprise a latch or an output stage.

3. A circuit as recited in claim 1, wherein said source transistor supplies power to an output stage, or a latch, or a combination of latch and output stage within the integrated circuit.

4. A circuit as recited in claim 1:
wherein said means for modulating the state of said source transistor, comprises: a circuit configured for receiving a selection signal and communicating said selection signal through a first path delay to said source transistors prior to communicating said selection signal through a second path delay to the logic transistors; and
wherein said first path delay is less than said second path delay for stabilizing source power prior to activating the logic transistors.

5. A circuit as recited in claim 4, wherein said selection signal comprises a chip select or block select signal.

6. A circuit as recited in claim 1, wherein said means for modulating the state of said source transistor, comprises a circuit configured for using the timing difference between asynchronous and synchronous signals to activate said source transistors prior to the logic transistors of the device.

7. A circuit as recited in claim 6, wherein said asynchronous signal is configured for arrival prior to the synchronous signal in response to a positive device setup time.

8. A circuit as recited in claim 6, wherein the asynchronous signal is a chip select signal or block select signal, and the synchronous signal is a clock signal or a signal synchronized with the clock.

9. A circuit as recited in claim 6, wherein said asynchronous signal is adapted for modulating the state of source transistors for a first logic group, and said synchronous signal is adapted for modulating the state of source transistors for a second or subsequent logic group.

10. A circuit as recited in claim 1, wherein said means for modulating the state of said source transistor, comprises a circuit for controlling the source power between a low-power non-active voltage level and a voltage level sufficient to support normal device activity.

11. A circuit as recited in claim 10, wherein said circuit comprises an error amplifier whose output level is controlled by a reference voltage, and whose activity state is determined by a device selection signal or block selection signal.

12. A circuit as recited in claim 1, further comprising means for maintaining the source transistor in an on condition for a period of time after the logic transistors are turned off.

13. A circuit as recited in claim 12, wherein said means for maintaining said source transistor in an on condition, comprises a circuit configured for activating the source transistor upon receiving an active selection signal, and for delaying the deactivation of the source transistor for a desired period of time after the selection signal returns inactive.

14. A circuit as recited in claim 13, wherein said selection signal comprises a chip select or block select signal.

15. A circuit for controlling source transistors within an integrated circuit device, comprising:
at least one source transistor configured for selectively supplying power to an integrated circuit device having logic transistors;
wherein said source transistor is configured as a power source transistor, a ground source transistor, or a combination of both power source transistor and ground source transistor, and
means for modulating the state of said source transistor in response to changes in the operating mode of the integrated circuit device to turn on said source transistor and maintain said source transistor in the on state for a period of time after said logic transistor is turned off.

16. A circuit for controlling source voltage within an integrated circuit device, comprising:
a latch circuit having at least two logic transistors coupled for retaining a binary state and configured for being accessed for reading or writing in an access mode;
at least one source connection, either power or ground, through which a virtual source potential can be maintained; and
a means for driving said source connection from a low-power non-active voltage level to a normal access voltage level;
wherein said normal access voltage level is configured for supporting normal device read and write access in the device.

17. A circuit as recited in claim 16, wherein said low-power non-active mode comprises a standby or idle mode which is implemented with or without data retention.

18. A circuit as recited in claim 16, wherein said latch comprises:
at least two CMOS inverters in which the output of the first inverter is connected to the input of the second inverter, and the output of the second inverter is connected to the input of the second inverter, and the sources of the PMOS transistors of the first and second inverter are connected to a given first node, and the sources of the NMOS transistors of the first and second inverter are connected to a given second node;

19. A circuit as recited in claim 16, wherein said source connection is coupled to said first or said second node, and wherein an alternate node, first or second, is coupled to a power source or a power source transistor, or is connected to a ground source or a ground source transistor.

20. A circuit as recited in claim 16, wherein said means for driving said source connection is configured for varying the voltage potential of the first node in response to integrated circuit operating mode.

21. A circuit as recited in claim 20:
wherein said means for driving said source connection comprises an amplifier configured for controlling the voltage potential of said source connection in response to receiving a reference voltage; and
wherein said reference voltage is dynamically or statically programmed.

22. A circuit as recited in claim 16, wherein a first access path is connected to the output of the first inverter, or a second access path is connected to the output of the second inverter, or a first and second access path are connection to the output of the first and second inverter, respectively.

23. A circuit as recited in claim 16, wherein said access path is controlled by address selection circuitry which turns off said access path irrespective of the address information change when operating in at least one mode which is not normal access mode.

24. A circuit as recited in claim 16, wherein said access path is turned off when there is no address change after a given period of time has elapsed.

25. A circuit as recited in claim 16, wherein said source connections are controlled according to the state of the access path.

26. A circuit as recited in claim 16, further comprising latch circuitry configured for storing address information when the access path is turned off, and for recovering address information from this latch when the access path gate is turned on.

27. A method of controlling low-power operations in an integrated circuit device, comprising:
detecting a first selection signal;
activating source transistors for supplying power to an output stage, latch, or combination of latch with output stage within the integrate circuit, in response to receipt of said first selection signal; and
activating logic transistors within said integrated circuit after activating said source transistors;
wherein a sufficient delay is provided between activating the source transistors and activating the logic transistors to stabilize power from said source transistors.

28. A method as recited in claim 27, further comprising, deactivating said source transistors within said integrated circuit after deactivating said logic transistors.

29. A method as recited in claim 28, wherein a sufficient delay is provided between deactivating the logic transistors and deactivating the source transistors to prevent loss of power stabilization.

30. A method as recited in claim 28, further comprising introducing a sufficient delay period between the deactivation of the logic transistors and the source transistors to reduce operating power losses arising from frequent switching of the source transistors on and off.
